(19) United States
(12) Patent Application Publication
(10) Pub. No.: US 2013/0247971 A1
(43) Pub. Date: Sep. 26, 2013

(54) Oxygen Containing Precursors for Photovoltaic Passivation

(71) Applicants: Mary Kathryn Haas, Emmaus, PA (US); Anupama Mallikarjunan, Macungie, PA (US); Robert Gordon Ridgeway, Quakertown, PA (US); Katherine Anne Hutchison, Sunnyvale, CA (US); Michael T Savo, Bethlehem, PA (US)

(72) Inventors: Mary Kathryn Haas, Emmaus, PA (US); Anupama Mallikarjunan, Macungie, PA (US); Robert Gordon Ridgeway, Quakertown, PA (US); Katherine Anne Hutchison, Sunnyvale, CA (US); Michael T Savo, Bethlehem, PA (US)

(73) Assignee: AIR PRODUCTS AND CHEMICALS, INC., Allentown, PA (US)

(21) Appl. No.: 13/610,311

(22) Filed: Sep. 11, 2012

Related U.S. Application Data
(60) Provisional application No. 61/536,748, filed on Sep. 20, 2011.

(51) Int. Cl. H01L 31/0216

(52) U.S. Cl. CPC H01L 31/02168
USPC 136/256; 438/72

(57) ABSTRACT

Methods for depositing a passivation layer on a photovoltaic cell are disclosed. Methods include depositing a passivation layer comprising at least a bi-layer further comprising a silicon oxide and a silicon nitride layer. The silicon precursor(s) used for the deposition of the silicon oxide layer or the silicon nitride layer, respectively, is selected from the family of Si(OR¹)ₓR²_{y}, or from the family of SiRₓH_{y}, silane, and combinations thereof; wherein x+y=4, y≠4; R¹ is C₁-C₈ alkyl; R² is selected from the group consisting of hydrogen, C₁-C₈ alkyl, and NR*₃; R is C₁-C₈ alkyl or NR*₃; wherein R* can be hydrogen or C₁-C₈ alkyl; C₁-C₈ alkyl can be linear, branched or cyclic, the ligand can be saturated, unsaturated, or aromatic (for cyclic alkyl). Photovoltaic devices containing the passivation layers are also disclosed.

### CROSS-REFERENCE TO RELATED APPLICATIONS

This application claims the benefit of U.S. Provisional Application No. 61/536,748 filed Sep. 20, 2011 the disclosure of which is incorporated by reference in its entirety.

### BACKGROUND OF THE INVENTION

The present invention is directed to the field of silicon-based dielectric materials produced by CVD methods. In particular, it is directed to methods for making films of such materials and their use as passivation or barrier coatings in photovoltaic devices.

Photovoltaic (“PV”) cells convert light energy into electrical energy. Many photovoltaic cells are fabricated using either monocrystalline silicon or multicrystalline silicon as substrates. The silicon substrates in the cells are commonly modified with a dopant of either positive or negative conductivity type, and are on the order of 50-500 microns in thickness. Throughout this application, the surface of the substrate, such as a wafer, intended to face incident light is designated as the front surface and the surface opposite the front surface is referred to as the rear surface. By convention, positively doped silicon is commonly designated as “p”, where holes are the majority electrical carriers. Negatively doped silicon is designated as “n” where electrons are the majority electrical carrier. The key to the operation of a photovoltaic cell is the creation of a p-n junction, usually formed by further doping a thin layer at the front surface of the silicon substrate (FIG. 1). Such a layer is commonly referred to as the emitter layer, while the bulk silicon is referred to as the absorber layer. The emitter may be either p-doped or n-doped depending on the configuration of the device.

A key requirement for optimal photovoltaic device efficiency is effective passivation of the front and rear surfaces of the silicon. The surface of any solid typically represents a large disruption from the crystal periodicity of the bulk, and thus generates a higher population of sub-stoichiometric bonding resulting in electrical defects. For silicon, when these defects occur energetically within the range of the band gap, they increase carrier recombination and negatively impact device efficiency. When the silicon surface is coated with a passivation layer (PL), the properties of the silicon-PL become critical. Again, the crystal periodicity of bulk silicon is interrupted due to the presence of non-silicon atoms at the interface.

Silicon-PL interface charge can play a critical role in influencing effectiveness of passivation. Fixed charge generated during PL deposition can create an induced field in the underlying silicon (Aberle, Progress in Photovoltaics, 8, 473). For a passivation layer in contact with n-type silicon, a high positive fixed charge is desired in order to decrease carrier recombination. For a passivation layer in contact with p-type silicon, a reduced positive fixed charge is desired in order to decrease carrier recombination and prevent parasitic shunting.

In addition to functioning as a passivation layer, the dielectric material may provide anti-reflective properties in order to reduce reflectivity and increase light absorption.

A process for making photovoltaic devices incorporating SiNxHy passivation is described by Leguijt and Wanka, (WO08043827A; Solar Energy Materials and Solar Cells, 40, 297) where the passivation layer is deposited using silane and ammonia. The process results in a high positive fixed charge at the interface of typically >+1e12/cm2. Therefore the process is compatible for passivation in contact with n-type silicon, but produces inferior results when in contact with p-type silicon (Dauwe, Progress in Photovoltaics, 10, 271).

A process for making photovoltaic devices incorporating thermally grown silicon oxide is described in US2009151784A. The process requires high temperatures in range of 800-1000 C and may result in slow processing times. The process is known to produce a fixed interface charge on the order of e11/cm2 which is compatible with passivation of p-type silicon surfaces.

A process for making photovoltaic devices incorporating chemically grown silicon oxide is also described by Naber (34^{th} IEEE PVSC 2009). The process requires nitric acid treatment with potentially long immersion times.

A process for making photovoltaic devices incorporating CVD oxide/nitride stacked layers is described by Hofmann (Advances in Optoelectronics, 485467), using silane with N₂O, O₂, or ammonia. The process reports surface recombination velocities of below 700 cm/s for a two-layer stack system. Subsequently, an annealing in forming gas at 425° C. for 15 minutes has been brought down the carrier lifetime measurements below 50 cm/s. A thermal treatment of approximately 850° C. for about 3 seconds increased the carrier lifetime to <70 cm/s. The deposition of silane oxide films may require high plasma power density and deposition temperature due to the bond strength of Si—H present in the silane precursor.

A process for creating a passivation coating while simultaneously forming a p-n junction is described by Krygowski (PVSC, 2007). Precursors such as tetraethylorthosilicate (TEOS) are used to coat a substrate in the liquid phase. The chemical is activated thermally at temperatures above 700 C in an air (oxygen containing) environment.

A process for creating a silicon oxide passivation film using tetraethylorthosilicate (TEOS) is described by Leguijt (WO08043827A; Solar Energy Materials and Solar Cells, 40, 297). The PECVD films are deposited using TEOS and N2O as an oxygen source, with the two chemicals in a 1:1 ratio. All samples showed surface recombination velocities (SRV)>10⁵ cm/sec directly after deposition. Measured surface recombination velocities were between 600-5000 cm/sec directly after anneal for 30 minutes in forming gas at 400 C. The samples showed degradation over time the anneal treatment.

A process for creating a silicon oxide passivation film using TEOS, hexamethyldisiloxane (HMDSO), or octamethylcyclotetrasiloxane (OMCTS) as the PECVD silicon precursor is described by Hoex (JVST A, 2006). Films in the study were deposited using an excess of oxygen. SRV values after deposition were >10³ cm/sec. An SRV value of 54 cm/sec on n-type FZ silicon after 15 minute post-deposition anneal in forming gas at 600 C.

Therefore, there is a need for depositing a CVD oxide passivation films or layers using precursors that provide excellent interface properties in contact with p-type silicon, at deposition temperatures less than 450 C, without the addition of a length post anneal step, with manufacturable throughput and cost of ownership. Optionally, a nitride film may be deposited on top of the oxide film (FIG. 2). The passivation layer may be present at the front side of the device, rear side of the device, or both.

### BRIEF SUMMARY OF THE INVENTION

This invention relates to methods for producing a passivation layer for photovoltaic devices; and the photovoltaic devices thereof.

In one aspect, there is provided a method for depositing at least one passivation layer on a photovoltaic cell in a chamber comprising steps of:
providing the photovoltaic cell having a front surface and a rear surface;
providing a first silicon precursor;
depositing a silicon oxide layer having a thickness ranging from 5 to 70 nm at least on one surface of the photovoltaic cell;
providing a second silicon precursor;
providing a nitrogen source; and
depositing a silicon nitride layer having a thickness ranging from 20 to 200 nm on the silicon oxide layer;
wherein the at least one passivation layer having a thickness ranging from 25 to 600 nm comprising at least one bi-layer comprising both the silicon oxide layer and the silicon nitride layer.

In another aspect, there is provided a photovoltaic device comprising:
a photovoltaic cell comprising:
   a P-doped silicon layer adjacent a N-doped silicon layer,
   a front surface and a rear surface;
and
at least one passivation layer deposited on at least one surface of the photovoltaic cell by the disclosed method.

In yet another aspect, there is provided a photovoltaic device comprising:
a photovoltaic cell comprising
   a P-doped silicon layer adjacent a N-doped silicon layer,
   a front surface and a rear surface;
and
at least one passivation layer having a thickness ranging from 25 to 600 nm deposited on at least one of the surfaces of the photovoltaic cell;
wherein the passivation layer having at least one bi-layer comprising of a silicon oxide layer having a thickness ranging from 5 to 70 nm and a silicon nitride layer having a thickness ranging from 20 to 200 nm.

The silicon oxide layer in the passivation layer is deposited by using at least one silicon precursor selected from the family of Si(OR¹)ₓR²_{y}; wherein

x+y=4, and y≠4;

R¹ is independently selected from the group consisting of
C1-C8 linear alkyl, wherein the ligand is saturated or unsaturated;
C1-C8 branched alkyl, wherein the ligand may be saturated or unsaturated;
C1-C8 cyclic alkyl, wherein the ligand may be saturated, unsaturated, or aromatic; and

R² is independently selected from the group consisting of
hydrogen;
C1-C8 linear alkyl, wherein the ligand is saturated or unsaturated;
C1-C8 branched alkyl, wherein the ligand may be saturated or unsaturated;
C1-C8 cyclic alkyl, wherein the ligand may be saturated, unsaturated, or aromatic; and
NR³₃; wherein R³ can be independently selected from the group consisting of hydrogen; and linear, branched, cyclic, saturated, or unsaturated alkyl.

The silicon nitride layer in the passivation layer is deposited by using at least one silicon precursor selected from the group consisting of silane, the family of SiRₓH_{y}, and combinations thereof;

wherein x+y=4, y≠4; and

R is independently selected from the group consisting of
C1-C8 linear alkyl, wherein the ligand is saturated or unsaturated; examples are methyl, ethyl, butyl, propyl, hexyl, ethylene, allyl, 1-butylene, 2-butylene;
C1-C8 branched alkyl, where the ligand may be saturated or unsaturated; examples are isopropyl, isopropylene, isobutyl, tert-butyl;
C1-C8 cyclic alkyl, where the ligand may be saturated, unsaturated, or aromatic; examples are cyclopentyl, cyclohexyl, benzyl, methylcyclopentyl; and
NR*₃ where R* can be independently hydrogen; or linear, branched, cyclic, saturated, or unsaturated alkyl.

The oxide layer is optionally deposited with the addition of oxygen source, such as O₂, N₂O, ozone, hydrogen peroxide, NO, NO₂, N₂O₄, or mixtures, to the chamber.

The nitrogen source includes but not limited to NH₃, methylamine, dimethylamine, trimethylamine, or mixtures thereof.

Examples of silicon precursors from the family of Si(OR¹)ₓR²_{y} include but not limited to methoxysilane, dimethoxysilane, trimethoxysilane, tetramethoxysilane, tetrapropoxysilane, ethoxysilane, diethoxysilane, triethoxysilane, dimethoxydiethoxysilane, methoxytriethoxysilane, ethoxytrimethoxysilane, methylethoxysilane, ethylethoxysilane, ethyldiethoxysilane, ethyltriethoxysilane, methyltriethoxysilane, dimethyldiethoxysilane, dimethylethoxysilane, diethyldiethoxysilane, methylethoxysilane, ethylethoxysilane, methyltrimethoxysilane, trimethylethoxysilane, n-propyltriethoxysilane, iso-propyltriethoxysilane, n-butyltriethoxysi lane, tert-butyltriethoxysilane, and iso-butyltriethoxysilane.

Examples of silicon precursors from the family of SiRₓH_{y} include but not limited to methylsilane, dimethylsilane, trimethylsilane, tetramethylsilane, ethylsilane, diethylsilane, tetraethylsilane, propylsilane, dipropylsilane, isobutylsilane, tertbutylsilane, dibutylsilane, methylethylsilane, dimethyldiethylsilane, methyltriethylsilane, ethyltrimethylsilane, isopropylsilane, diisopropylsilane, triisopropylsilane, disopropylaminosilane, aminosilane, diaminosilane, methylaminosilane, ethylaminosilane, diethylaminosilane, dimethylaminosilane, bis-tertbutylaminosilane, and bis-isopropylamino(methylvinylsilane).

### BRIEF DESCRIPTION OF SEVERAL VIEWS OF THE DRAWINGS

FIG. 1. Four representative photovoltaic device configurations illustrating the presence of passivation layer(s).

FIG. 2. Schematic of silicon oxide passivation layer coated with optional silicon nitride layer.

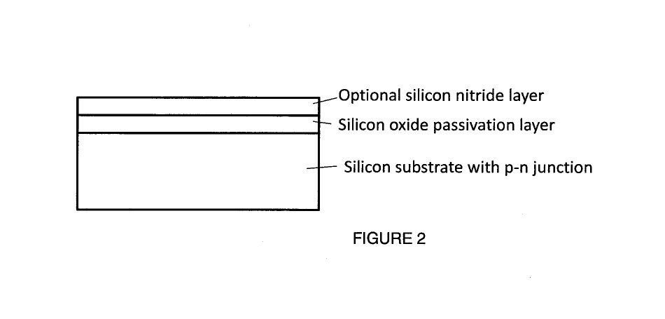

FIG. 3. Plot of minority carrier lifetime as a function of minority carrier density for p-type silicon with a passivation layer a bi-layer containing a tetraethylorthosilicate (TEOS) oxide layer and a second layer of triethylsilane nitride after a firing.

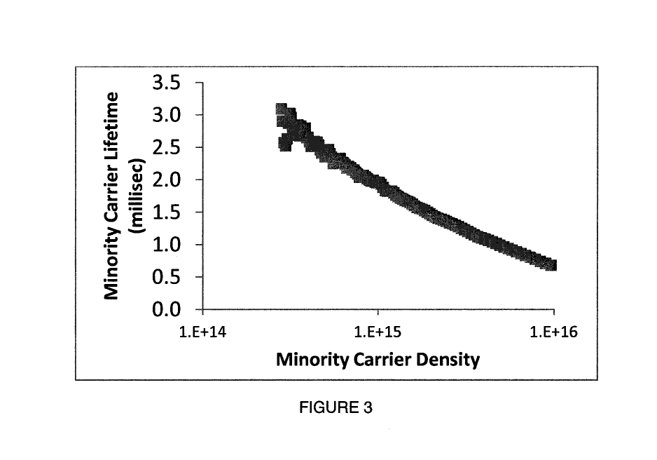

### DETAILED DESCRIPTION OF THE INVENTION

In one aspect, the present invention relates to the deposition methods for producing a passivation layer or film for photovoltaic devices.

One of the methods comprises steps of:
providing the photovoltaic cell having a front surface and a rear surface;
providing a silicon precursor;
depositing a silicon oxide layer at least on one surface of the photovoltaic cell;
wherein the passivation layer is the silicon oxide layer.

The silicon precursor is selected from the family of Si(OR¹)ₓR²_{y}; wherein

x+y=4, and y≠4;

R¹ is independently selected from the group consisting of
C1-C8 linear alkyl, wherein the ligand is saturated or unsaturated;
C1-C8 branched alkyl, wherein the ligand may be saturated or unsaturated; and
C1-C8 cyclic alkyl, wherein the ligand may be saturated, unsaturated, or aromatic;

and

R² is independently selected from the group consisting of
hydrogen;
C1-C8 linear alkyl, wherein the ligand is saturated or unsaturated;
C1-C8 branched alkyl, wherein the ligand may be saturated or unsaturated;
C1-C8 cyclic alkyl, wherein the ligand may be saturated, unsaturated, or aromatic; and
NR³₃; wherein R³ can be independently selected from the group consisting of hydrogen; and linear, branched, cyclic, saturated, or unsaturated alkyl.

The silicon oxide layer may be deposited with the addition of an oxygen source selected from the group consisting of O₂, N₂O, ozone, hydrogen peroxide, NO, NO₂, N₂O₄, and mixtures thereof.

If an oxygen source is used and the oxygen source volumetric flow is less than 20% of the silicon precursor volumetric flow, then the use of a less than stoichiometric or catalytic oxygen source level may serve to accelerate deposition rate, while still relying on the silicon precursor ligands to form the bulk of the silicon oxide film.

The oxide film is more preferably deposited without the addition of oxygen source to the CVD reaction chamber.

Without wishing to be bound by theory, the deposition with lower or no added oxygen source flow may result in improved film and chamber uniformity.

Additional layers may optionally be deposited on top of the silicon oxide layer. For example, silicon nitride, silicon carbide, silicon carbonitride, transparent conductive oxide, aluminum oxide, amorphous silicon.

For example, a silicon nitride film (or layer) can be deposited to cover the silicon oxide film (or layer) on one or both silicon surfaces of a photovoltaic device.

Another method comprises steps of:
providing the photovoltaic cell having a front surface and a rear surface;
providing a first silicon precursor;
depositing a silicon oxide layer at least on one surface of the photovoltaic cell;
providing a second silicon precursor;
providing a nitrogen source; and
depositing a silicon nitride layer on the silicon oxide layer;
wherein the passivation layer comprising a bi-layer comprising further both the silicon oxide layer and the silicon nitride layer.

The first silicon precursor is selected from the family of Si(OR¹)ₓR²_{y}; wherein

x+y=4, and y≠4;

R¹ is independently selected from the group consisting of
C1-C8 linear alkyl, wherein the ligand is saturated or unsaturated;
C1-C8 branched alkyl, wherein the ligand may be saturated or unsaturated; and
C1-C8 cyclic alkyl, wherein the ligand may be saturated, unsaturated, or aromatic;

and

R² is independently selected from the group consisting of
hydrogen;
C1-C8 linear alkyl, wherein the ligand is saturated or unsaturated;
C1-C8 branched alkyl, wherein the ligand may be saturated or unsaturated;
C1-C8 cyclic alkyl, wherein the ligand may be saturated, unsaturated, or aromatic; and
NR³₃; wherein R³ can be independently selected from the group consisting of hydrogen; and linear, branched, cyclic, saturated, or unsaturated alkyl.

The second silicon precursor is selected from the group consisting of silane, the family of SiRₓH_{y}; wherein x+y=4, y≠4, and R is independently selected from the group consisting of C1-C8 linear alkyl, wherein the ligand is saturated or unsaturated; examples are methyl, ethyl, butyl, propyl, hexyl, ethylene, allyl, 1-butylene, 2-butylene; C1-C8 branched alkyl, where the ligand may be saturated or unsaturated; examples are isopropyl, isopropylene, isobutyl, tert-butyl; C1-C8 cyclic alkyl, where the ligand may be saturated, unsaturated, or aromatic; examples are cyclopentyl, cyclohexyl, benzyl, methylcyclopentyl; and NR^{*}₃ where R* can be independently hydrogen; or linear, branched, cyclic, saturated, or unsaturated alkyl.

In this case, the passivation layer is a bi-layer having both silicon oxide layer and silicon nitride layer.

The silicon oxide layer may be again deposited with the addition of an oxygen source selected from the group consisting of O₂, N₂O, ozone, hydrogen peroxide, NO, NO₂, N₂O₄, and mixtures thereof.

For example, the passivation layer can be a bi-layer, wherein the silicon nitride layer is deposited by using silane and ammonia.

A passivation layer can also contain multiple bi-layers.

This invention also relates to a photovoltaic device comprising
a photovoltaic cell comprising:
   a P-doped silicon layer adjacent a N-doped silicon layer,
   a front surface and a rear surface;
and
at least one passivation layer deposited on at least one of the surfaces, using at least one silicon precursor selected from the family of selected from the family of Si(OR¹)ₓR²_{y}; wherein

x+y=4, and y≠4;

R¹ is independently selected from the group consisting of
C1-C8 linear alkyl, wherein the ligand is saturated or unsaturated;
C1-C8 branched alkyl, wherein the ligand may be saturated or unsaturated; and
C1-C8 cyclic alkyl, wherein the ligand may be saturated, unsaturated, or aromatic;

and

R² is independently selected from the group consisting of
Hydrogen;
C1-C8 linear alkyl, wherein the ligand is saturated or unsaturated;
C1-C8 branched alkyl, wherein the ligand may be saturated or unsaturated;
C1-C8 cyclic alkyl, wherein the ligand may be saturated, unsaturated, or aromatic; and
NR³₃; wherein R³ can be independently selected from the group consisting of hydrogen; and linear, branched, cyclic, saturated, or unsaturated alkyl;
   wherein the passivation layer is a silicon oxide film.

This invention also relates to a photovoltaic device comprising
a photovoltaic cell comprising:
   a P-doped silicon layer adjacent a N-doped silicon layer,
   a front surface and a rear surface;
and
at least one passivation layer deposited on at least one of the surfaces;
wherein the at least one passivation layer is deposited by using a first silicon precursor selected from the family of selected from the family of Si(OR¹)ₓR²_{y}; wherein

x+y=4, and y≠4;

R¹ is independently selected from the group consisting of
C1-C8 linear alkyl, wherein the ligand is saturated or unsaturated;
C1-C8 branched alkyl, wherein the ligand may be saturated or unsaturated; and
C1-C8 cyclic alkyl, wherein the ligand may be saturated, unsaturated, or aromatic;

and

R² is independently selected from the group consisting of
Hydrogen;
C1-C8 linear alkyl, wherein the ligand is saturated or unsaturated;
C1-C8 branched alkyl, wherein the ligand may be saturated or unsaturated;
C1-C8 cyclic alkyl, wherein the ligand may be saturated, unsaturated, or aromatic; and
NR³₃; wherein R³ can be independently selected from the group consisting of hydrogen; and linear, branched, cyclic, saturated, or unsaturated alkyl; and
a second silicon precursor selected from silane, the family of SiRₓH_{y}, and combinations thereof; wherein

x+y=4, and y≠4;

R is independently selected from the group consisting of
C1-C8 linear alkyl, wherein the ligand is saturated or unsaturated;
C1-C8 branched alkyl, wherein the ligand may be saturated or unsaturated;
C1-C8 cyclic alkyl, wherein the ligand may be saturated, unsaturated, or aromatic;
and
NR*₃; wherein R* can be independently selected from the group consisting of hydrogen; and linear, branched, cyclic, saturated, or unsaturated alkyl.

Preferably, the C1-C8 linear alkyl is selected from the group consisting of methyl, ethyl, butyl, propyl, hexyl, ethylene, allyl, 1-butylene, and 2-butylene; the C1-C8 branched alkyl is selected from the group consisting of isopropyl, isopropylene, isobutyl, and tert-butyl; the C1-C8 cyclic alkyl is selected from the group consisting of cyclopentyl, cyclohexyl, benzyl, and methylcyclopentyl.

In this case, the passivation layer is a bi-layer having both silicon oxide layer and silicon nitride layer.

The silicon oxide layer or film may be deposited with an added oxygen source selected from the group consisting of O₂, N₂O, ozone, hydrogen peroxide, NO, NO₂, N₂O₄, and mixtures thereof.

The oxide film is more preferably deposited without the added oxygen source to the CVD reaction chamber.

Deposition of the silicon nitride layer/film may utilize a nitrogen source includes but not limited to NH₃, methylamine, dimethylamine, trimethylamine, or mixtures thereof.

Silicon precursors suitable for depositing the silicon oxide layer in the present invention include but are not limited to methoxysilane, dimethoxysilane, trimethoxysilane, tetramethoxysilane, tetra-n-proproxylsilane (or tetrapropoxysilane), ethoxysilane, diethoxysilane, triethoxysilane, tetraethylorthosilicate (or tetraethoxysilane), dimethoxydiethoxysilane, methoxytriethoxysilane, ethoxytrimethoxysilane, methylethoxysilane, ethylethoxysilane, ethyldiethoxysilane, ethyltriethoxysilane, methyltriethoxysilane, dimethyldiethoxysilane, dimethylethoxysilane, diethyldiethoxysilane, methyldiethoxysilane, methylethoxysilane, ethylethoxysilane, methyltrimethoxysilane, trimethylethoxysilane, n-propyltriethoxysilane, iso-propyltriethoxysi lane, n-butyltriethoxysilane, tert-butyltriethoxysi lane, iso-butyltriethoxysilane.

Silicon precursors suitable for depositing the silicon nitride layer in the present invention include but not limited to methylsilane, dimethylsilane, trimethylsilane, tetramethylsilane, ethylsilane, diethylsilane, triethylsilane, tetraethylsilane, propylsilane, dipropylsilane, isobutylsilane, tertbutylsilane, dibutylsilane, methylethylsilane, dimethyldiethylsilane, methyltriethylsilane, ethyltrimethylsilane, isopropylsilane, diisopropylsilane, triisopropylsilane, disopropylaminosilane, aminosilane, diaminosilane, methylaminosilane, ethylaminosilane, diethylaminosilane, dimethylaminosilane, bis-tertbutylaminosilane, and bis-isopropylamino(methylvinylsilane).

It should be understood that the silicon oxide layer/film also refers to silicon dioxide layer/file. The silicon oxide layer may include low concentrations of carbon and hydrogen. The concentration of carbon is preferably less than 5% atomic, and the concentration of hydrogen is preferably less than 20% atomic.

It should be understood that the silicon nitride layer/film will contain a measurable concentration of hydrogen, consistent with amorphous films known in the art.

In one embodiment, a photovoltaic cell, such as, for example, a photovoltaic cell according to the present invention is fabricated using a doped substrate comprising silicon, typically in the form of a wafer or a ribbon. The substrate can comprise monocrystalline silicon and multicrystalline silicon. As used herein, “silicon” includes monocrystalline silicon and multicrystalline silicon unless expressly noted. One or more layers of additional material; for example, germanium, may be disposed over the substrate surface or incorporated into the substrate if desired. Although boron is widely used as the p-type dopant, other p-type dopants such as, for example, gallium or indium, can also be employed. Although phosphorous is widely used as an n-type dopant, other dopants may be used. Thus, the photovoltaic cell, the silicon substrate or the substrate are exchangeable.

Silicon substrates are typically obtained by slicing silicon ingots, vapor phase deposition, liquid phase epitaxy or other known methods. Slicing can be via inner-diameter blade, continuous wire or other known sawing methods. Although the substrate can be cut into any generally flat shape, wafers are typically circular in shape. Generally, such wafers are typically less than about 500 micrometers thick. Preferably, substrates of the present invention are less than about 200 micrometers thick.

Before further processing, the substrate is preferably cleaned to remove any surface debris and cutting damage. Typically, this includes placing the substrate in a wet chemical bath such as, for example, a solution comprising any one of a base and peroxide mixture, an acid and peroxide mixture, a NaOH solution, or several other solutions known and used in the art. The temperature and time required for cleaning depends on the specific solution employed.

Optionally (especially for monocrystalline substrates), the substrate is texturized by, for example, anisotropic etching of the crystallographic planes. Texturing is commonly in the form of pyramid-shapes depressed or projected from the substrate surface. The height or depth of the pyramid-shapes varies with processing, but is typically from about 1 to about 7 micrometers. One or both sides of the solar cell may be textured.

An emitter layer is formed typically by doping the substrate with a dopant electrically opposite to that present in the bulk. N-doping can be accomplished by depositing the n-dopant onto the substrate and then heating the substrate to “drive” the n-dopant into the substrate. Gaseous diffusion can be used to deposit the n-dopant onto the substrate surface. Other methods can also be used, however, such as, for example, ion implantation, solid state diffusion, or other methods used in the art to create an n-doped layer and a shallow p-n junction proximal to the substrate surface. Phosphorus is a preferred n-dopant, but any suitable n-dopant can be used alone or in combination such as, for example, arsenic, antimony or lithium. Conversely, boron doping may be applied using similar methods. After emitter formation, a p-n junction is created along all exposed of the surfaces of the substrate. In some embodiments, it may be necessary to remove a doped region from one side or from the edges of the wafer during subsequent processing.

The emitter doping process may create a layer of silicon oxide on the exposed surfaces of the wafer, which is typically removed prior to application of a passivation coating. The silicon oxide can be removed through, for example, chemical etching in a wet chemical bath, typically a low concentration HF solution.

In one embodiment, local high density doping may then be performed in order to generate areas of selective emitters.

Prior to deposition of a passivation layer or film, the substrate may be cleaned using acidic or basic solutions known in the art.

The films depositions of the present invention are compatible with the various chemical processes used to produce photovoltaic devices, and are capable of adhering to a variety of materials. For example, the deposition is chemical vapor deposition (CVD) or plasma enhanced chemical vapor deposition (PECVD).

In the bi-layer embodiment, the silicon oxide layer is typically 5 to 70 nm in thickness, preferably 5 to 45; and the silicon nitride layer is typically 20 to 200, preferably 30 to 150 nm in thickness. The passivation layers can have multiple bi-layers. The passivation layer of the present invention is deposited to a total thickness typically from about 25 to 600 nm, preferably, 40 to about 500 nm. The thickness can be varied as required, one bi-layer (comprising the silicon oxide layer and the silicon nitride layer), and/or multiple bi-layer can be applied.

Preferably, the passivation films according to the present invention have a refractive index between 1.0 and 4.0 and, more preferably, between 1.7 and 2.3. Improved reflectivity over a range of wavelengths can be achieved with two or more films. For example, the more layers of the antireflective coating according to the present invention, the greater the range of wavelengths over which the reflectivity can be minimized. Typically with multiple layers, each layer will have a different refractive index.

Liquid precursors can be delivered to the reactor system by any number of means, preferably using a pressurized stainless steel vessel fitted with the proper valves and fittings to allow the delivery of liquid to the process reactor.

Additional materials can be charged into the vacuum chamber prior to, during and/or after the deposition reaction. Such materials include, e.g., inert gas (e.g., He, Ar, N₂, Kr, Xe, etc., which may be employed as a carrier gas for lesser volatile precursors) and reactive substances, such as gaseous or liquid organic substances, NH₃, and H₂.

Energy is applied to the gaseous reagents to induce the gases to react and to form the layer/film on the substrate. Such energy can be provided by (depending on the method employed), e.g., thermal, plasma, pulsed plasma, helicon plasma, high density plasma, inductively coupled plasma, and remote plasma methods. A secondary rf frequency source can be used to modify the plasma characteristics at the substrate surface. Preferably, the coating is formed by plasma enhanced chemical vapor deposition. The plasma frequency may range from 10 KHz to 40 MHz depending on the deposition system. The chamber configuration may be single or multi wafer, and direct or remote plasma.

The flow rate for each of the gaseous reagents preferably ranges from 10 to 10,000 sccm, and are highly dependent on the volume of the chamber. The flow rate for the silicon precursors preferably ranges from 10 sccm to 1700 sccm; the flow rate for the oxygen source preferably ranges from 2 to 17000 sccm; and the flow rate for the nitrogen source preferably ranges from 200 to 17000 sccm.

Methods for adding contacts to a wafer substrate for a photovoltaic cell are known in the art. Front and rear contacts are applied to the substrate using one of multiple known methods: photolithographic, laser grooving and electroless plating, screen printing, or any other method that provides good ohmic contact with the front and rear surfaces respectively such that electric current can be drawn from the photovoltaic cell. Typically, the contacts are present in a design or pattern, for example a grid, fingers, lines, etc., and do not cover the entire front or rear surface. After applying the contacts, the substrate may be fired (a rapid anneal or heat treatment), typically at a temperature of from about 700 to about 950° C. for only several seconds, such as 1-10 seconds, to form contacts to the substrate.

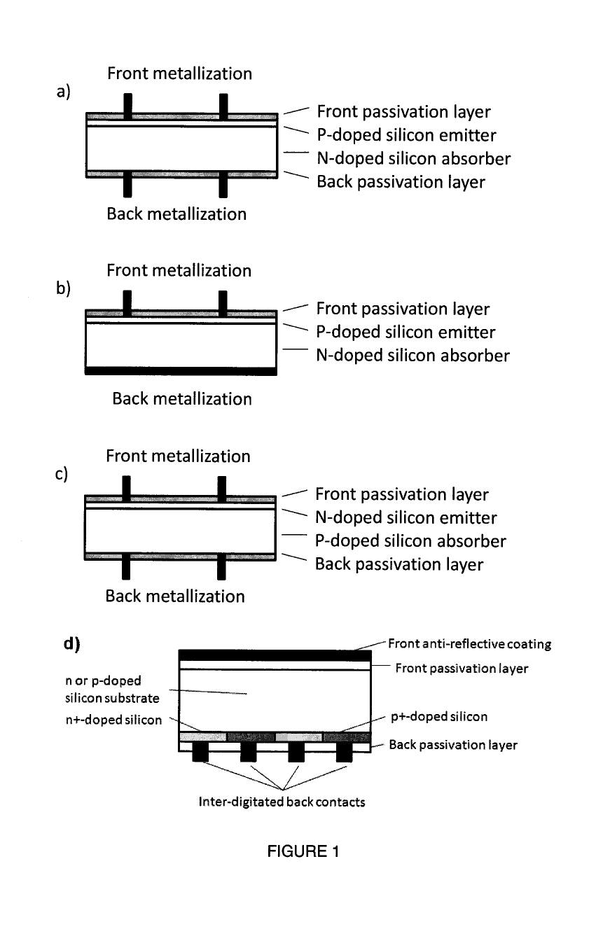

Four possible device configurations are presented in FIG. 1. The invention is compatible with devices where the p-n junction is formed at the front of the device (FIG. 1a, 1b, 1c).

The invention is also compatible with device configurations such as metal-wrap through contacts, interdigitated rear contacts (FIG. 1d), or interdigitated front contacts. In these devices, the p-n junction is not formed homogeneously at the front of the device. However, an effective passivation layer/film remains critical to device performance.

Passivation layer/film generated using the present invention may provide the benefit of increased internal reflectance when used on the rear side of a device, due to the influence of the film's refractive index on degree of Fresnel reflection over the full angular range. Increased internal reflection generally provides higher device efficiency.

Passivation layer/film generated using the present invention may provide an additional benefit of anti-reflection when used on the front side of the device. Optimization of layer/film thickness to refractive index can minimize the amount of light that is reflected away from the front side of the device. Decreased front reflectance generally leads to increased device efficiency.

Passivation layer/film generated using the present invention do not substantially degrade during firing at 800° C. for 4 seconds. Preferably, less than 20% reduction in surface lifetime occurs. More preferably, there is an improvement in surface carrier lifetime.

Passivation layers having one bi-layer stack, has a surface recombination lifetime values of <200 cm/sec, preferably <100 cm/sec, and most preferably <30 cm/sec.

The invention will be illustrated in more detail with reference to the following Examples, but it should be understood that the present invention is not deemed to be limited thereto.

### EXAMPLES

Bond energy calculations were performed using the density functional based Dmol3 module of commercially available Materials Studio package.

Depositions in Examples 2-4 were performed on p-type Float Zone silicon substrates having a resistivity of 1000-2000 Ω-cm after a three step RCA cleaning to remove organic and metal surface impurities and HF surface treatment to remove native oxide.

For Examples 5-7, depositions were performed on p-type Float Zone silicon substrates having a resistivity of 1-5 Ω-cm.

There silicon substrates were all 500 micrometers.

Depositions were performed on both sides of the silicon substrate in order to allow measurement of surface recombination lifetime using a Sinton lifetime tester.

Depositions were performed on a 200 mm single wafer PECVD platform at 13.56 MHz. Deposition temperature ranged from 200-450° C. Chamber pressure ranged from 2-10 torr. Electrode spacing ranged from 200-800 mil.

For all examples, 15 nm of silicon oxide layer was deposited directly on the silicon substrate, and covered with 85 nm of silicon nitride layer.

### Example 1

Bond energies were calculated for silane, and several alkoxy silanes as shown in Table I. In contrast to silane, the alkoxy substituted versions have ligands with lower thermodynamic bond energies. Not wishing to be bound by theory, it is hypothesized that the lower bond energies (i.e. O—C) allow formation of a silicon oxide at lower plasma power densities and deposition temperature which provides enhanced passivation performance. It is hypothesized that the high bond strength of Si—O in the compounds allows retention of this species in the plasma and allows deposition without the addition of a separate oxygen source.

TABLE I
Calculated bond energies for silane and alkyl silane molecules

| | Si—H | O—C | Si—O |
|---|---|---|---|
| Molecule | bond energy | bond energy | bond energy |
| Silane | 95 kcal/mole | N/A | N/A |
| Trimethoxysilane | 97 kcal/mole | 86 kcal/mole | 100 kcal/mole |
| Tetramethoxysilane | N/A | 87 kcal/mole | 112 kcal/mole |
| Tetra-n-proproxylsilane | N/A | 84 kcal/mole | 111 kcal/mole |
| Tetraethylorthosilicate | N/A | 86 kcal/mole | 108 kcal/mole |

### Example 2

Depositions were performed using tetraethylorthosilicate, or tetraethoxysilane, or TEOS to deposit a 15 nm silicon oxide layer/film on the surface of a silicon substrate. No added, separate oxygen source was used in the deposition process.

For the 85 nm silicon nitride layer, triethylsilane and ammonia were used to deposit the layer on the top of the silicon oxide film.

Flow rates for silicon oxide deposition were: 500 mg/min or 53.8 sccm for TEOS; 1000 sccm for He. The chamber pressure was 8 torr; power was 910 W. The deposition temperatures was set at 400° C.

Flow rates for silicon nitride deposition were 125 mg/min or 24 sccm for triethylsilane; 225 sccm for NH₃; 400 sccm for He. The chamber pressure was 3 torr; power was 400 W. The deposition temperatures were set at 350° C.

TEOS film A and TEOS film B were deposited at the same deposition condition on two substrates.

Lifetime data were collected using a Sinton lifetime tester in transient mode and recorded for minority carrier lifetime values of 1e15 and 5e14. Lifetime and surface recombination velocity were shown in Table II.

TABLE II
Minority carrier lifetime and surface recombination velocity for
TEOS films after PECVD deposition without O₂

| | Lifetime at | Lifetime at | SRV at | SRV at |
|---|---|---|---|---|
| Precursor | 5e14 MCD | 1e15 MCD | 5e14 MCD | 1e15 MCD |
| TEOS film A | 0.22 millisec | 0.16 millisec | 113 cm/sec | 156 cm/sec |
| TEOS film B | 0.29 millisec | 0.23 millisec | 86 cm/sec | 108 cm/sec |

Surface recombination velocity was determined using the equation SRV=t/2(T) where t is the silicon thickness in cm and T is the measured lifetime in seconds. Each of the film resulted in SRV values less than 160 cm/sec, in contrast to Hofman et al (Advances in Optoelectronics, 485467), who reported 700 cm/sec for bi-layer after deposition using monosilane for both silicon oxide and silicon nitride without heat treatments, such as, firing or/and annealing.

### Example 3

TEOS films from example 2 were heated using a belt furnace at a peak temperature of 800° C. for less than 10 seconds.

Lifetime and surface recombination velocity were shown in Table III.

TABLE III
Minority carrier lifetime and surface recombination velocity
for TEOS films after rapid anneal (R.A.) heat treatment

| | Lifetime at | Lifetime at | SRV at | SRV at | % |
|---|---|---|---|---|---|
| | 5e14 | 1e15 | 5e14 | 1e15 | improve- |
| Precursor | MCD | MCD | MCD | MCD | ment |
| TEOS film | 2.4 | 1.9 | 10.4 | 13.2 | ~160% |
| A after R.A. | millisec | millisec | cm/sec | cm/sec | |
| TEOS film | 2.1 | 1.7 | 11.9 | 14.7 | ~150% |
| B after R.A. | millisec | millisec | cm/sec | cm/sec | |

After the heat treatment at about 800° C. for only several seconds, the surface recombination lifetime value is improved more than 150%.

The heat treatment, which is typical of that experienced during screen print metallization, results in a significant improvement in lifetime. In contrast to the prior art, the passivation performance improvement occurs during the existing metallization process, and no anneal steps are added to the overall process sequence.

### Example 4

Depositions were performed using the same condition as in Example 2 except with an added oxygen source. TEOS was used to deposit a 15 nm silicon oxide layer/film on the surface of a silicon substrate with an added, separate oxygen source O₂.

For the 85 nm silicon nitride layer, triethylsilane and ammonia were used to deposit the layer on the top of the silicon oxide film.

Flow rates for silicon oxide deposition were: 500 mg/min or 53.8 sccm for TEOS; 1000 sccm for O₂, and 1000 sccm for He. The chamber pressure was 8 torr; power was 910 W. The deposition temperatures was set at 400° C.

Flow rates for silicon nitride deposition were 125 mg/min or 24 sccm for triethylsilane; 225 sccm for NH₃; 400 sccm for He. The chamber pressure was 3 torr; power was 400 W. The deposition temperatures were set at 350° C.

TEOS film C and TEOS film D were deposited at the same deposition conditions on two substrates.

Lifetime and surface recombination velocity were shown in Table IV.

TABLE IV
Minority carrier lifetime and surface recombination velocity
for TEOS films after PECVD deposition with O₂

| | Lifetime at | Lifetime at | SRV at | SRV at |
|---|---|---|---|---|
| Precursor | 5e14 MCD | 1e15 MCD | 5e14 MCD | 1e15 MCD |
| TEOS film C | 1.40 millisec | 0.95 millisec | 17.9 cm/sec | 26.3 cm/sec |
| TEOS film D | 1.86 millisec | 1.25 millisec | 13.4 cm/sec | 20.0 cm/sec |

The surface recombination lifetime values were <30 cm/sec without performing the firing or rapid annealing.

### Example 5

A passivation stack consisting of 15 nm silicon oxide capped with 85 nm silicon nitride using TEOS for oxide deposition and triethylsilane for nitride deposition exactly the same as Example 4 above but formed on Float Zone silicon having a resistivity of 1-5 Ω-cm.

For the 15 nm silicon oxide layer, deposition was performed using tetraethylorthosilicate (TEOS) to deposit the oxide film on the surface of a silicon substrate. A separate oxygen source was used with TEOS in the deposition process.

For the 85 nm silicon nitride layer, triethylsilane and ammonia were used to deposit the layer on the top of the silicon oxide film.

Flow rates for silicon oxide deposition were: 500 mg/min or 53.8 sccm for TEOS; 1000 sccm for O₂; 1000 sccm for He. The chamber pressure was 8 torr; power was 800 W. The deposition temperatures was set at 350° C.

Flow rates for silicon nitride deposition were 125 mg/min or 24 sccm for triethylsilane; 225 sccm for NH₃. The chamber pressure was 3 torr; power was 400 W. The deposition temperatures were set at 350° C.

The deposited passivation layer yielded a silicon device having a minority carrier lifetime of 373 μsec and/or an SRV of 134 cm/sec.

Since there was no measurable difference of carrier lifetime at 5e14 or 1e15, thus the minority carrier lifetime and the SRV were averaged values at 5e14 or 1e15.

### Example 6

Example 6 was performed under similar conditions as Example 5 but the triethylsilane nitride deposition was done using BKM parameters for optimized lifetime.

For the 15 nm silicon oxide layer, deposition was performed using tetraethylorthosilicate (TEOS) to deposit the oxide film on the surface of a silicon substrate. A separate oxygen source was used with TEOS in the deposition process.

For the 85 nm silicon nitride layer, triethylsilane and ammonia were used to deposit the layer on the top of the silicon oxide film.

Flow rates for silicon oxide deposition were: 500 mg/min or 53.8 sccm for TEOS; 1000 sccm for O₂; 1000 sccm for He. The chamber pressure was 8 torr; power was 800 W. The deposition temperatures was set at 350° C.

Flow rates for silicon nitride deposition were 100 mg/min or 19.3 sccm for triethylsilane; 800 sccm for NH₃. The chamber pressure was 3 torr; power was 400 W. The deposition temperatures were set at 400° C.

The deposited passivation layer yielded a silicon device having a minority carrier lifetime of 433 μsec or an SRV of 115 cm/sec.

### Example 7

Example 7 was performed under similar conditions as Example 6 but the TEOS oxide deposition and triethylsilane nitride deposition were both done using BKM parameters for optimized lifetime.

For the 15 nm silicon oxide layer, deposition was performed using tetraethylorthosilicate (TEOS) to deposit the oxide film on the surface of a silicon substrate. A separate oxygen source was used with TEOS in the deposition process.

For the 85 nm silicon nitride layer, triethylsilane and ammonia were used to deposit the layer on the top of the silicon oxide film.

Flow rates for silicon oxide deposition were: 165 mg/min or 53.8 sccm for TEOS; 1365 sccm for O₂; 650 sccm for He. The chamber pressure was 8 torr; power was 200 W. The deposition temperatures was set at 375° C.

Flow rates for silicon nitride deposition were 100 mg/min or 19.3 sccm for triethylsilane; 800 sccm for NH₃. The chamber pressure was 3 torr; power was 400 W. The deposition temperatures were set at 400° C.

The deposited passivation layer yielded a silicon device having a minority carrier lifetime of 528 μsec or an SRV of 97.7 cm/sec.

The foregoing examples should be taken as illustrating, rather than as limiting the present invention as defined by the claims. As will be readily appreciated, numerous variations and combinations of the features set forth above can be utilized without departing from the present invention as set forth in the claims. Such variations are intended to be included within the scope of the following claims.

1. A method for depositing at least one passivation layer on a photovoltaic cell in a chamber comprising steps of:
providing the photovoltaic cell having a front surface and a rear surface;
providing a first silicon precursor;
depositing a silicon oxide layer having a thickness ranging from 5 to 70 nm at least on one surface of the photovoltaic cell;
providing a second silicon precursor;
providing a nitrogen source; and
depositing a silicon nitride layer having a thickness ranging from 20 to 200 nm on the silicon oxide layer;
wherein the at least one passivation layer having a thickness ranging from 25 to 600 nm comprising at least one bi-layer comprising both the silicon oxide layer and the silicon nitride layer.

2. The method of claim 1, wherein
the first silicon precursor is selected from the family of Si(OR¹)ₓR²_{y}; wherein
x+y=4, and y≠4;
R¹ is independently selected from the group consisting of
C1-C8 linear alkyl, wherein the ligand is saturated or unsaturated;
C1-C8 branched alkyl, wherein the ligand may be saturated or unsaturated; and
C1-C8 cyclic alkyl, wherein the ligand may be saturated, unsaturated, or aromatic;
and
R² is independently selected from the group consisting of
Hydrogen;
C1-C8 linear alkyl, wherein the ligand is saturated or unsaturated;
C1-C8 branched alkyl, wherein the ligand may be saturated or unsaturated;
C1-C8 cyclic alkyl, wherein the ligand may be saturated, unsaturated, or aromatic; and
NR³₃; wherein R³ can be independently selected from the group consisting of hydrogen; and linear, branched, cyclic, saturated, or unsaturated alkyl;
and
the second silicon precursor is selected from silane, the family of SiRₓH_{y}, and combinations thereof; wherein
x+y=4, and y≠4;
R is independently selected from the group consisting of
C1-C8 linear alkyl, wherein the ligand is saturated or unsaturated;
C1-C8 branched alkyl, wherein the ligand may be saturated or unsaturated;
C1-C8 cyclic alkyl, wherein the ligand may be saturated, unsaturated, or aromatic;
and
NR*₃; wherein R* can be independently selected from the group consisting of hydrogen; and linear, branched, cyclic, saturated, or unsaturated alkyl.

3. The method of claim 2, wherein
the C1-C8 linear alkyl is selected from the group consisting of methyl, ethyl, butyl, propyl, hexyl, ethylene, allyl, 1-butylene, and 2-butylene;
the C1-C8 branched alkyl is selected from the group consisting of isopropyl, isopropylene, isobutyl, and tert-butyl;
the C1-C8 cyclic alkyl is selected from the group consisting of cyclopentyl, cyclohexyl, benzyl, and methylcyclopentyl.

4. The method of claim 2, wherein
the first silicon precursor is selected from the group consisting of: methoxysilane, dimethoxysilane, trimethoxysilane, tetramethoxysilane, tetrapropoxysilane, ethoxysilane, diethoxysilane, triethoxysilane, dimethoxydiethoxysilane, methoxytriethoxysilane, ethoxytrimethoxysilane, methylethoxysilane, ethylethoxysilane, ethyldiethoxysilane, ethyltriethoxysilane, methyltriethoxysilane, dimethyldiethoxysilane, dimethylethoxysilane, diethyldiethoxysilane, methylethoxysilane, ethylethoxysilane, methyltrimethoxysilane, trimethylethoxysilane, n-propyltriethoxysilane, iso-propyltriethoxysi lane, n-butyltriethoxysilane, tert-butyltriethoxysi lane, iso-butyltriethoxysilane and combinations thereof; and
the second silicon precursor is selected from the group consisting of: silane, methylsilane, dimethylsilane, trimethylsilane, tetramethylsilane, ethylsilane, diethylsilane, tetraethylsilane, propylsilane, dipropylsilane, isobutylsilane, tertbutylsilane, dibutylsilane, methylethylsilane, dimethyldiethylsilane, methyltriethylsilane, ethyltrimethylsilane, isopropylsilane, diisopropylsilane, triisopropylsilane, disopropylaminosilane, aminosilane, diaminosilane, methylaminosilane, ethylaminosilane, diethylaminosilane, dimethylaminosilane, bis-tertbutylaminosilane, and bis-isopropylamino(methylvinylsilane); and combinations thereof.

5. The method of claim 1 wherein the first silicon precursor is selected from the group consisting of tetraethylorthosilicate, tetrapropoxysilane, diethoxymethylsilane and mixtures thereof; and the second silicon precursor is selected from the group consisting of triethylsilane, trimethyl silane, tetramethyl silane, and combinations thereof.

6. The method of claim 1, wherein depositing method is chemical vapor deposition or plasma enhanced chemical vapor deposition.

7. The method of claim 1 wherein the depositing is performed without added oxygen source.

8. The method of claim 1 wherein the depositing of the silicon oxide layer is performed with flowing an added oxygen source selected from the group consisting of O₂, N₂O, ozone, hydrogen peroxide, NO, NO₂, N₂O₄, and mixtures thereof to the chamber.

9. The method of claim 1, wherein the nitrogen source flowing at a rate from 500 to 10,000 sccm into the chamber; the first silicon precursor and the second silicon precursor flowing at a rate independently from 10 sccm to 1700 sccm into the chamber.

10. The method of claim 1, wherein the silicon oxide layer is deposited at a temperature between 200° C. and 400° C.; and the silicon nitride layer is deposited at a temperature between 300° C. and 450° C.

11. The method of claim 1, wherein the passivation layer has a surface recombination velocity <200 cm/s.

12. The method of claim 1, wherein the passivation layer has a surface recombination velocity <100 cm/s.

13. The method of claim 1, wherein the passivation layer has a surface recombination velocity <30 cm/s.

14. The method of claim 1, wherein the silicon oxide layer having a thickness ranging from 5 to 45 nm; and the silicon nitride layer having a thickness ranging from 30 to 150 nm.

15. A photovoltaic device comprising:
a photovoltaic cell comprising:
a P-doped silicon layer adjacent a N-doped silicon layer,
a front surface and a rear surface;
and
at least one passivation layer deposited on the photovoltaic cell by the method of claim 7.

16. A photovoltaic device comprising:
a photovoltaic cell comprising:
a P-doped silicon layer adjacent a N-doped silicon layer,
a front surface and a rear surface;
and
at least one passivation layer deposited on the photovoltaic cell by the method of claim 8.

17. A photovoltaic device comprising:
a photovoltaic cell comprising
a P-doped silicon layer adjacent a N-doped silicon layer,
a front surface and a rear surface;
and
at least one passivation layer having a thickness ranging from 25 to 600 nm deposited on at least one of the surfaces of the photovoltaic cell;
wherein the passivation layer having at least one bi-layer comprising a silicon oxide layer having a thickness ranging from 5 to 70 nm and a silicon nitride layer having a thickness ranging from 20 to 200 nm.

18. The photovoltaic device of claim 17, wherein the passivation layer has a surface recombination velocity <200 cm/s.

19. The photovoltaic device of claim 17, wherein the passivation layer has a surface recombination velocity <30 cm/s.

20. The photovoltaic device of claim 17, wherein the silicon oxide layer having a thickness ranging from 5 to 45 nm; and the silicon nitride layer having a thickness ranging from 30 to 150 nm.
